(19) United States
(12) Patent Application Publication
(10) Pub. No.: US 2010/0270592 A1
(43) Pub. Date: Oct. 28, 2010

(54) SEMICONDUCTOR DEVICE

(75) Inventor: Doyeol AHN, Seoul (KR)

Correspondence Address: Workman Nydegger;1000 Eagle Gate Tower, 60 East South Temple, Salt Lake City, UT, 84111, US

(73) Assignee: University of Seoul Industry Cooperation Foundation, Seoul (KR)

(21) Appl. No.: 12/430,406

(22) Filed: Apr. 27, 2009

(51) Int. Cl. H01L 29/205; H01L 21/20; H01L 29/225

(52) U.S. Cl. 257/201; 438/478; 257/E29.091; 257/E29.097; 257/E21.09

(57) ABSTRACT

Semiconductor devices having at least one barrier layer with a wide energy band gap are disclosed. In some embodiments, a semiconductor device includes at least one active layer, and at least one barrier layer disposed on at least one surface of the at least one active layer. The at least one barrier layer has a wider energy band gap than the energy band gap of the at least one active layer. The compounds of the active layer and the barrier layer may be selected to reduce relaxation time of an electron or hole in the active layer.

### BACKGROUND

Group III-V compound and Group II-VI compound semiconductors have particularly wide band gaps and are capable of emitting green or blue light. Recently semiconductor devices, such as photo-electric conversion devices using III-V or II-VI group compound semiconductor crystals as base materials have been developed to improve efficiency and life time of the semiconductor devices.

However, one drawback to Group III-V compound and Group II-VI compound semiconductors are their poor optical gain characteristics.

### SUMMARY

In one embodiment, a semiconductor device includes at least one active layer composed of a first compound, and at least one barrier layer composed of a second compound and disposed on at least one surface of the at least one active layer. The at least one barrier layer has an energy band gap that is wider than the energy band gap of the at least one active layer. The first and/or second compounds may be selected to reduce relaxation time of an electron or hole in the at least one active layer.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

FIGS. 1(a) and (b) are schematic diagrams of an illustrative embodiment of a semiconductor device.

FIGS. 2(a) and (b) are schematic diagrams showing band gaps of the semiconductor device of FIG. 1.

FIGS. 3(a) and (b) are schematic diagrams illustrating an electron-phonon scattering and a carrier-carrier scattering, respectively.

FIG. 4 is a schematic diagram of an illustrative embodiment of a III-V group compound semiconductor device.

FIG. 5 is a graph showing an internal polarization field as a function of In composition of the AlGaInN barrier layer shown in FIG. 4.

FIG. 6 is a graph showing the relationship between In composition of the InGaN active layer and In composition of the AlGaInN barrier layer shown in FIG. 4.

FIG. 7 is a graph showing the relationship between an internal polarization field and a scattering rate in the III-V group compound semiconductor device of FIG. 4.

FIG. 8 is a graph showing an optical gain as a function of a transition wavelength for the III-V group compound semiconductor device shown in FIG. 4 and a InGaN/GaN semiconductor device.

FIG. 9 is a schematic diagram of an illustrative embodiment of a II-VI group compound semiconductor device.

FIG. 10 is a graph showing internal polarization field as a function of Mg composition of the MgZnO barrier layer for different Cd compositions of the CdZnO active layer shown in FIG. 9.

FIG. 11 shows graphs illustrating (a) the relationship between Mg composition of the MgZnO barrier layer and Cd composition of the CdZnO active layer shown in FIG. 9, and (b) a transition wavelength of the semiconductor device as a function of Cd composition of the CdZnO active layer shown in FIG. 9.

FIG. 12 shows graphs illustrating (a) an optical gain as a function of a transition wavelength for different mole fractions of Cd compositions of the CdZnO active layer shown in FIG. 9, and (b) an optical gain as a function of different mole fractions of Cd compositions of the CdZnO active layer shown in FIG. 9.

FIGS. 13(a)-(e) are schematic diagrams illustrating an illustrative embodiment of a method for fabricating a semiconductor device.

### DETAILED DESCRIPTION

In one embodiment, a semiconductor device includes at least one active layer composed of a first compound, and at least one barrier layer composed of a second compound and disposed on at least one surface of the at least one active layer. An energy band gap of the at least one barrier layer can be wider than an energy band gap of the at least one active layer. The first and/or second compounds can be selected to reduce a relaxation time of an electron or hole in the at least one active layer.

The compositions of the first and/or second compounds can be selected to reduce a scattering rate of the electron or hole in the at least one active layer to reduce the relaxation time. Further, the compositions of the first and/or second compounds can be selected to reduce an internal polarization field in the at least one active layer to reduce the scattering rate. Still further, the compositions of the first and/or second compounds can be selected to make a sum of piezoelectric and spontaneous polarizations in the at least one active layer and a sum of piezoelectric and spontaneous polarizations in the at least one barrier layer substantially the same to reduce the internal polarization field.

Each of the first and second compounds can include a III-V group compound semiconductor material or a II-VI group compound semiconductor material. The first compound can include, for example, GaN, InGaN, CdZnO, AlN, AlP, AlAs, GaP, GaAs, InN, InP, InAs, AlGaN, AlGaP, AlGaAs, InGaN, InGaP, InGaAs, INAlN, InAlP, InAlAs, AlGaInN, AlGaInP, AlGaInAs, ZnO, ZnS, CdO, CdS, CdZnS, CdZnO, MgZnO, MgZnS, CdMgZnO, or CdMgZnS. The second compound can include, for example, AlInGaN, InGaN, AlGaN, AlGaP, AlGaAs, InGaN, InGaP, InGaAs, InAlN, InAlP, InAlAs, AlGaInP, AlGaInAs, CdZnS, CdZnO, MgZnO, MgZnS, CdMgZnO, or CdMgZnS.

In some embodiments, the first compound can include InₓGa₁₋ₓN (0≦x≦1) and the second compound can include Al_{y1}Ga_{1-y1-y2}In_{y2}N (0≦y1+y2≦1). Variable x can be in the range of about 0.05 and 0.15, variable y1 can be in the range of about 0.05 to 0.3, and variable y2 can be in the range of about 0.1 and 0.22.

In some embodiments, the first compound can include CdₓZn₁₋ₓO (0≦x≦1) and the second compound can include Mg_{y}Zn_{1-y}O (0≦y≦1). Variable x can be in the range of about 0 and 0.20, and variable y can be in the range of about 0.01 and 0.80.

The at least one active layer can have a thickness of about 0.1 nm to 300 nm, and the at least one barrier layer can have a thickness of about 0.1 nm to 500 nm.

In some embodiments, the energy band gap of the at least one active layer can be in the range of about 0.7 eV and 3.4 eV, and the energy band gap of the at least one barrier layer can be in the range of about 0.7 eV and 6.3 eV. In other embodiments, the energy band gap of the at least one active layer can be in the range of about 2.2 eV and 3.35 eV, and the energy band gap of the at least one barrier layer can be in the range of about 3.35 eV and 5.3 eV.

In another embodiment, a method for fabricating a semiconductor device includes forming at least one active layer composed of a first compound on a substrate, and forming at least one barrier layer composed of a second compound on at least one surface of the at least one active layer. An energy band gap of the at least one barrier layer is wider than an energy band gap of the at least one active layer. The compositions of the first and/or second compounds can be adjusted to reduce relaxation time of an electron or hole in the at least one active layer. Further, the compositions of the first and/or second compounds can be adjusted to reduce an internal polarization field in the at least one active layer

Each of the first and second compounds can include a III-V group compound semiconductor material or a II-VI group compound semiconductor material. In some embodiments, when the first compound includes InₓGa₁₋ₓN and the second compound includes Al_{y1}Ga_{1-y1-y2}In_{y1}N, the compositions of the first and/or second compounds can be adjusted by controlling a variable x in the range of 0-1, and a sum of variables y1 and y2 in the range of 0-1. In other embodiments, when the first compound includes CdₓZn₁₋ₓO and the second compound includes Mg_{y}Zn_{1-y}O, the compositions of the first and/or second compounds can be adjusted by controlling each of variables x and y in the range of 0-1.

The at least one active layer can have a thickness of about 0.1 nm to 300 nm and the at least one barrier layer can have a thickness of about 0.1 nm to 500 nm Either the at least one active layer or the at least one barrier layer can be formed by employing radio-frequency (RF) magnetron sputtering, pulsed laser deposition, metal organic chemical vapor deposition (MOCVD), molecular beam epitaxy, or radio-frequency plasma-excited molecular beam epitaxy. The compositions of the first and/or second compounds can be adjusted by controlling an amount of precursor gases or by controlling a processing temperature or processing time to reduce the relaxation time of the electron or hole in the at least one active layer.

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

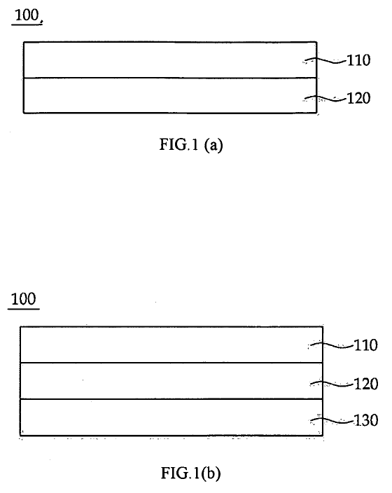

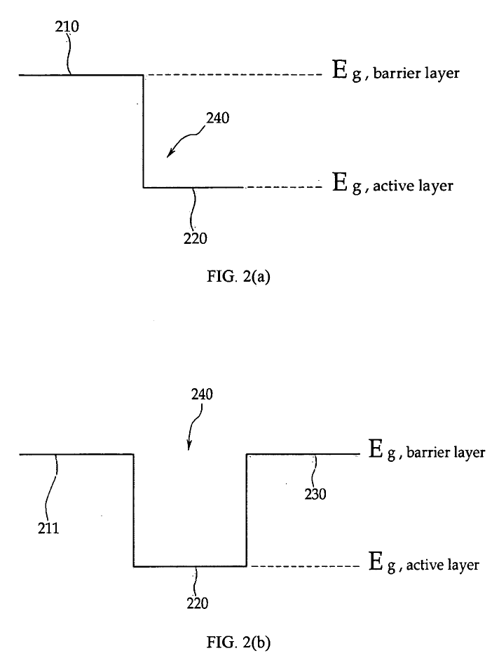

FIG. 1(a) and (b) are schematic diagrams of an illustrative embodiment of a semiconductor device 100. FIGS. 2(a) and (b) are schematic diagrams showing band gaps of semiconductor device 100 of FIG. 1.

As depicted in FIG. 1(a), semiconductor device 100 may have a single heterostructure in which a barrier layer 110 is disposed on one surface (e.g. a top surface) of an active layer 120. Barrier layer 110 has a wider band gap that is wider than the band gap of active layer 120. For example, as depicted in FIG. 2(a), a band gap (E_{g,active layer}) 220 of active layer 120 is lower than a band gap (E_{g,barier layer}) 210 of barrier layer 110, so that a quantum well 240 is formed in active layer 120. E_{g,active layer} is the difference between E_{c} and Eᵥ at active layer 120, and E_{g,barrier layer} is the difference between E_{c} and Eᵥ at barrier layer 110. E_{c} refers to an energy level at a conduction band of a semiconductor material, for example, a III-V group or II-VI group compound semiconductor. Eᵥ refers to an energy level at a valence band of a semiconductor material, such as III-V group or II-VI group compound without limitation. Quantum well 240 is a potential well which can confine carriers, such as electrons or holes, in a dimension perpendicular to a surface of active layer 120. Due to the band gap differences between active layer 120 and barrier layer 110, particles, such as electrons or holes, can be confined in quantum well 240.

As depicted in FIG. 1(b), semiconductor device 100 may optionally have a second barrier layer (e.g., a barrier layer 130), and thus form a double heterostructure. For example, semiconductor device 100 may have active layer 120, barrier layer 110 disposed on one surface (e.g., a top surface) of active layer 120, and barrier layer 130 disposed on the other surface (e.g., a bottom surface) of active layer 120. For the purpose of illustration, barrier layers 110 and 130 are hereinafter referred as upper barrier layer 110 and lower barrier layer 130. Each of upper and lower barrier layers 110 and 130 has a wider band gap than that of active layer 120. Quantum well 240 is formed in active layer 120 because band gap (E_{g,active layer}) 220 of active layer 120 is narrower than band gaps (E_{g,upper barrier layer}) 210 and (E_{g,lower barrier layer}) 230 of upper and lower barrier layers 110 and 130, as depicted in FIG. 2(b).

Active layer 120 may be composed of a III-V group compound semiconductor material or a II-VI group compound semiconductor material. For example, III-V group compound semiconductor materials of active layer 120 include, without limitation, GaN, InGaN, AlN, AlP, AlAs, GaP, GaAs, InN, InP, InAs, AlGaN, AlGaP, AlGaAs, InGaN, InGaP, InGaAs, INAlN, InAlP, InAlAs, AlGaInN, AlGaInP, or AlGaInAs. The II-VI group semiconductor material of active layer 120 may include, without limitation, ZnO, ZnS, CdO, CdS, CdZnO, CdZnS, MgZnO, MgZnS, CdMgZnO, or CdMgZnS. Each of upper and lower barrier layers 110 and 130 may be composed of a III-V group compound semiconductor material or a II-VI group compound semiconductor material. In some embodiments, each of upper barrier layer 110 and lower barrier layer 130 may also be composed of a ternary compound semiconductor material or a quaternary compound semiconductor material. The ternary or quaternary III-V group compound semiconductor material of each of upper barrier layer 110 and lower barrier layer 130 may include, without limitation, AlInGaN, InGaN, AlGaN, AlGaP, AlGaAs, InGaN, InGaP, InGaAs, InAlN, InAlP, InAlAs, AlGaInP, or AlGaInAs. The ternary or quaternary II-VI group compound semiconductor material of upper barrier layer 110 and lower barrier layer 130 may include, without limitation, CdZnS, MgZnS, CdZnO, MgZnO, CdMgZnO, or CdMgZnS.

In other embodiments, semiconductor device 100 can have two or more active layers and two or more barrier layers. For example, the two or more active layers and the two or more barrier layers can be sequentially deposited to form a sandwiched configuration in which an active layer is sandwiched with two barrier layers.

A quantum efficiency is a quantity defined as the percentage of photons that produces an electron-hole pair, and can be measured by, for example, an optical gain of semiconductor device 100. The optical gain g(ω) can be calculated by using a non-Markovian model with many-body effects due to interband transitions. In some examples, the “many-body effects” refer to a band gap renormalization and an enhancement of optical gain due to attractive electron-hole interaction (Coulomb or excitonic enhancement). The optical gain g(ω) is given by Equation (1) as below. For theory on the optical gain, see Doyeol Ahn, “Theory of Non-Markovian Gain in Strained-Layer Quantum-Well Lasers with Many-Body Effects”, IEEE Journal of Quantum Electronics, Vol. 34, No. 2, p. 344-352 (1998), and Ahn et al., “Many-Body Optical Gain and Intraband Relaxation Time of Wurtzite InGaN/GaN Quantum-Well Lasers and Comparison with Experiment”: Appl. Phys. Lett. Vol. 87, p. 044103 (2005), which are incorporated by references herein in their entireties.

$$g ( ω ) = \frac{ωμ c}{{n}_{r} V} {\sum }_{ση lm} {\sum }_{{\vec{k}}_{\vert \vert}} {\vert \hat{ɛ} \cdot {M}_{lm}^{ησ} ( {\vec{k}}_{\vert \vert} ) \vert}^{2} ( {f}_{c} - {f}_{h σ} ) {C}_{lm}^{ησ} ( {\vec{k}}_{\vert \vert} ) \qquad Equation ( 1 )$$

where ω is an angular frequency of a photon in active layer 120; μ is a vacuum permeability; nᵣ is a refractive index of active layer 120; c is a speed of light in free space; V is a volume of active layer 120; f_{c} and f_{hσ} are Fermi functions for a conduction band and a valence band of 3×3 block Hamiltonian H^{σ}, respectively; Mₗₘ^{ησ}(\vec{k}_{∥}) is a dipole matrix element between the conduction band with a spin state η and the valence band of the 3×3 block Hamiltonian H^{σ}; \hat{∈} is an unit vector in the direction of a photon polarization; and Cₗₘ^{ησ}(\vec{k}_{∥}) is a renormalized lineshape function.

The renormalized lineshape function Cₗₘ^{ησ}(\vec{k}_{∥}) is presented by Equation (2) below:

$${C}_{lm}^{ησ} ( {\vec{k}}_{\vert \vert} ) = \frac{1 + Re {g}_{2} ( ∞ , {Δ}_{lm}^{η σ} ( {\vec{k}}_{\vert \vert} ) )}{{( 1 - {Re q}_{lm}^{ησ} ( {\vec{k}}_{\vert \vert} ) )}^{2} + {( Im {q}_{lm}^{ησ} ( {\vec{k}}_{\vert \vert} ) )}^{2}} \times \{ \begin{matrix}Re {Ξ}_{lm}^{ησ} ( 0 , {Δ}_{lm}^{ησ} ( {\vec{k}}_{\vert \vert} ) ) ( 1 - Re {q}_{lm}^{ησ} ( {\vec{k}}_{\vert \vert} ) ) , \\ - Im {Ξ}_{lm}^{ησ} ( 0 , {Δ}_{lm}^{ησ} ( {\vec{k}}_{\vert \vert} ) ) Im {q}_{lm}^{ησ} ( {\vec{k}}_{\vert \vert} )\end{matrix} \} \qquad Equation ( 2 )$$

where the function g₂ is presented by the Equation (3) below.

$${g}_{2} ( t , {Δ}_{k} ) = {\int }_{0}^{\text{?}} d τ {\int }_{0}^{\text{?}} d \text{?} exp \{ i {Δ}_{k} \text{?} \} \cdot {\{ ( ( vk [ {H}_{\text{?}} ( t ) ( {\underline{U}}_{\text{?}} ( τ ) {H}_{\text{?}} ( t - τ ) ) ] \vert vk ) )}_{\text{?}} + {( ( ck \vert [ ( \underline{U} \text{?} ( τ ) {H}_{\text{?}} ( t - τ ) ) {H}_{\text{?}} ( t ) ] \vert ck ) )}_{\text{?}} \} \\ \text{?} \text{indicates text missing or illegible when filed} \qquad Equation ( 3 )$$

where \vec{k}_{∥} is an in-plane wave vector, Reqₗₘ^{ησ}(\vec{k}_{∥}) and Imqₗₘ^{ησ}(\vec{k}_{∥}) are the real and imaginary parts of Coulomb interaction between an electron in the conduction band with a spin state η and a hole in the valence band of 3×3 block Hamiltonian H^{σ} in the presence of photon fields, respectively. ReΞₗₘ^{ησ}(0,Δₗₘ^{ησ}(\vec{k}_{∥})) and Imσₗₘ^{ησ}(0,Δₗₘ^{ησ}(\vec{k}_{∥})) are the real and imaginary parts of the non-Markovian lineshape.

The real and imaginary parts of the non-Markovian lineshape are presented by Equations (4) and (5) below, respectively:

$$\begin{matrix}Re {Ξ}_{lm}^{ησ} ( 0 , {Δ}_{lm}^{ησ} ( {\vec{k}}_{\vert \vert} ) ) = \sqrt{\frac{{πτ}_{in} ( {\vec{k}}_{\vert \vert} , ℏω ) {τ}_{c}}{2 {ℏ}^{2}}} exp ( - \frac{{τ}_{in} ( {\vec{k}}_{\vert \vert} , ℏ ω ) {τ}_{c}}{2 {ℏ}^{2}} {{Δ}_{l m}^{η σ} ( {\vec{k}}_{\vert \vert} )}^{2} ) \\ and & Equation ( 4 ) \\ Im {Ξ}_{lm}^{ησ} ( 0 , {Δ}_{lm}^{ησ} ( {\vec{k}}_{\vert \vert} ) ) = \frac{{τ}_{c}}{ℏ} {\int }_{0}^{∞} exp ( - \frac{{τ}_{c}}{2 {τ}_{in} ( {\vec{k}}_{\vert \vert} , ℏω )} {t}^{2} ) sin ( \frac{{Δ}_{lm}^{ησ} ( {\vec{k}}_{\vert \vert} ) {τ}_{c}}{ℏ} t ) & Equation ( 5 )\end{matrix}$$

where τᵢₙ is relaxation time of carriers, and τ_{c} is correlation time for intraband process.

As shown in Equations (4) and (5), the abstract values of the real and imaginary parts of the non-Markovian lineshape ReΞₗₘ^{ησ}(0,Δₗₘ^{ησ}(\vec{k}_{∥})) and ImΞₗₘ^{ησ}(0,Δₗₘ^{ησ}(\vec{k}_{∥})) increase as the relaxation time τᵢₙ increases. Thus, since the renormalized lineshape function Cₗₘ^{ησ(\vec{k}}_{∥}) decreases when the non-Markovian lineshape increases according to the Equation (3), it decreases as the relaxation time increases. Accordingly, the optical gain g(ω) decreases as the relaxation time τᵢₙ increases according to Equation (1). Here, the relaxation time refers to the time period during which a carrier, such as an electron or hole, transits from a steady state to an equilibrium state. A carrier emits energy in the form of, for example, light, corresponding to the band gap between the steady state and the equilibrium state in quantum well 240 while the carrier undergoes the transition. Thus, for the same band gap between the steady state and the equilibrium state, as the relaxation time τᵢₙ decreases, an amount of the emitted energy per a time unit increases. Accordingly, the optical gain g(ω) will increase.

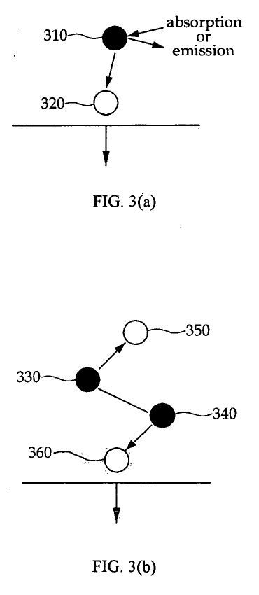

The relaxation time is related to an electron-phonon scattering and a carrier-carrier scattering in quantum well 240. FIGS. 3(a) and (b) show schematic diagrams illustrating an electron-phonon scattering and a carrier-carrier scattering, respectively. In some examples, the electron-phonon scattering refers to a situation where that a hole 320 is scattered due to the emission or absorption of phonon from or into an electron 310 (FIG. 3(a)). The carrier-carrier scattering refers to a situation where two electrons 330 and 340 collide and each scatter toward two holes 350 and 360. As the scatterings increase, the relaxation time τᵢₙ increases because the excited electrons and holes less frequently collide.

The scatterings are related to the intensity of an internal polarization field in quantum well 240. For example, when the internal polarization field exists in quantum well 240, it pushes electrons or holes to a wall of quantum well 240. Thus the effective well width is reduced, and the reduction results in the enhancement of the scattering rate. Accordingly, if the internal polarization field in quantum well 240 is reduced, the scattering rate can be decreased, and thus the relaxation time τᵢₙ can be decreased. As illustrated above, this results in the enhancement of the optical gain of quantum well 240.

The internal polarization field in quantum well 240 can arise from a spontaneous polarization P_{SP} and a piezoelectric polarization P_{PZ}. Spontaneous polarization P_{SP} refers to polarization that arises in ferroelectrics without external electric field. Piezoelectric polarization P_{PZ} refers to polarization that arises from electric potential generated in response to applied mechanical stress such as strain of a layer. Although P_{PZ} alone can be reduced by the reduction of the strain, P_{SP} still remains in quantum well 240. For additional detail on spontaneous and piezoelectric polarizations P_{SP} and P_{PZ} and the internal polarization field, see Ahn et al., “Spontaneous and piezoelectric polarization effects in wurtzite ZnO/MgZnO quantum well lasers”, Appl. Phys. Lett. Vol. 87, p. 253509 (2005), which is incorporated by reference herein in its entirety.

Thus, the scattering rate is decreased and thus the optical gain g(ω) is increased when a total internal polarization field, that includes the spontaneous and piezoelectric polarizations is reduced. The total internal polarization field F_{z}^{w} in quantum well 240 can be determined from the difference between the sum of P_{SP} and P_{PZ} in quantum well 240 and the sum of P_{SP} and P_{PZ} in upper barrier layer 110 or lower barrier layer 130. That is, internal polarization filed F_{z}^{w} can be presented by Equation (6) below.

F_{Z}^{W}=[(P_{SP}^{b}+P_{PZ}^{b})−(P_{SP}^{w}+P_{PZ}^{w})]/(∈^{w}+∈^{b}L_{w}/L_{b}) Equation (6)

where P is the polarization, the superscripts w and b denote quantum well 240 and upper and lower barrier layers 110 and 130, respectively, L is a thickness of quantum well 240 and upper and lower barrier layers 110 and 130, and ∈ is a static dielectric constant.

In some embodiments, internal polarization field F_{z}^{w} can have a value of zero by making the sum (P_{SP}^{b}+P_{PZ}^{b}) of spontaneous and piezoelectric polarizations at upper or lower barrier layer 110 or 130 and the sum (P_{SP}^{w}+P_{PZ}^{w}) of spontaneous and piezoelectric polarizations at quantum well 240 the same. For example, this can be achieved by controlling the mole fractions of the compounds in upper and lower barrier layers 110 and 130, and/or active layer 120.

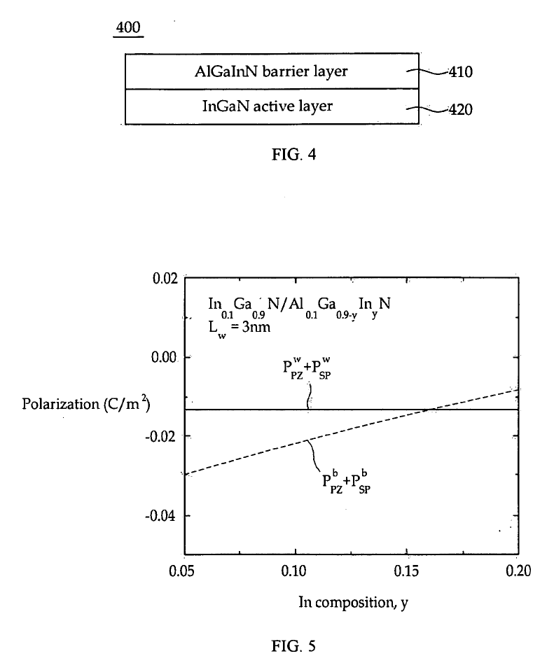

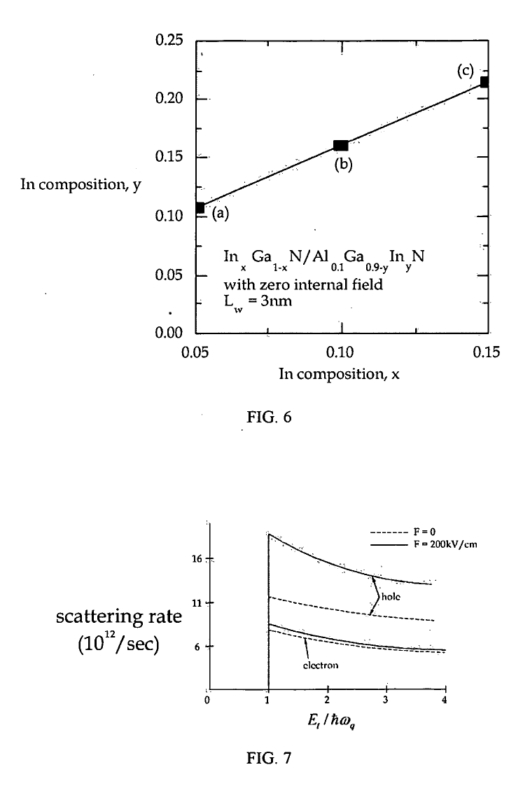

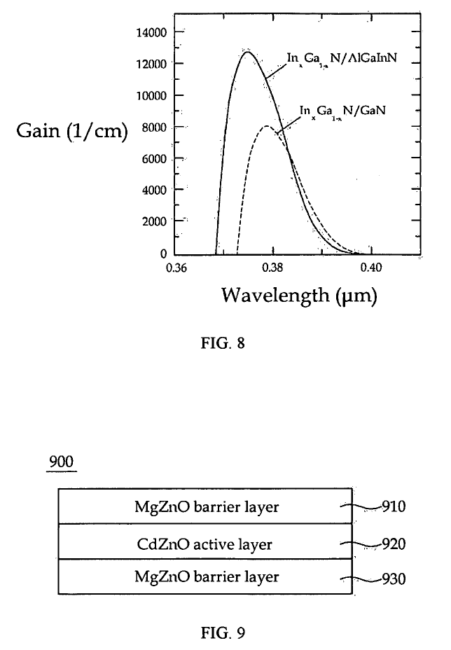

With reference to FIGS. 4 through 8, in a III-V group compound semiconductor device having a minimized internal polarization field will now be described. FIG. 4 is a schematic diagram of an illustrative embodiment of a III-V group compound semiconductor device. FIG. 5 is a graph showing internal polarization field as a function of In composition of the AlGaInN barrier layer depicted in FIG. 4. FIG. 6 is a graph showing the relationship between In composition of the InGaN active layer and In composition of the AlGaInN barrier layer depicted in FIG. 4. FIG. 7 is a graph showing the relationship between an internal polarization field and a scattering rate in the III-V group compound semiconductor device of FIG. 4. FIG. 8 is a graph showing an optical gain as a function of a transition wavelength for the III-V group compound semiconductor device depicted in FIG. 4 and a InGaN/GaN semiconductor device.

In some embodiments, as depicted in FIG. 4, a III-V group compound semiconductor device 400 includes an InGaN active layer 420 (i.e., an active layer composed of InGaN) and an AlGaInN barrier layer 410 (i.e. a barrier layer composed of AlGaInN) disposed on one surface (e.g. a top surface) of InGaN active layer 420 Alternatively, III-V group compound semiconductor device 400 may further have at least one additional barrier layer disposed under one surface (e.g. a bottom surface) of InGaN active layer 420. In some embodiments, InGaN active layer 420 may have a thickness of several nanometers to several hundreds nanometers (nm). In other embodiments, InGaN active layer 420 may have a thickness of about 0.1 nm to 300 nm, or about 1 nm to 50 nm.

In some embodiments, AlGaInN barrier layer 410 may have a thickness of several nanometers to several hundreds nanometers (nm). In other embodiments, barrier layer 410 may have a thickness of about 0.1 nm to 500 nm or about 1 nm to 100 nm. In some embodiments, a III-V group compound semiconductor material having a band gap wider than a band gap of a III-V group compound semiconductor material of the active layer can be selected for the barrier layer.

InGaN active layer 420 has a smaller band gap than the band gap of AlGaInN barrier layer 410, thus forming a quantum well in InGaN active layer 420. For example, the band gap of InGaN active layer 420 is in the range of about 0.7 eV and 3.4 eV, and the band gap of AlGaInN barrier layer 410 is in the range of about 0.7 eV and 6.3 eV. The difference between the band gaps of InGaN active layer 420 and AlGaInN barrier layer 410 can be controlled by adjusting the composition of InGaN active layer 420, the composition of barrier layer 410, or the compositions of both InGaN active layer 420 and AlGaInN barrier layer 410. In an illustrative example, aluminum (Al) composition of AlGaInN barrier layer 410 can be controlled so that AlGaInN barrier layer 410 has a larger band gap than that of InGaN active layer 420. For example, the composition of AlGaInN barrier layer 410 can be controlled to achieve a mole fraction of Al composition of the range of about 0.05 to 0.3, assuming that the total mole value of III group compound, that is, the sum of mole fractions of Al, In, and Ga, is one.

As illustrated with respect to Equation (6) above, the internal polarization field in the quantum well formed in InGaN active layer 420 can be reduced by controlling the mole fractions of the compositions of InGaN active layer 420 and AlGaInN barrier layer 410, which will now be described in detail.

The graph shown in FIG. 5 illustrates an internal polarization field (y-axis) depending on the mole fraction of indium (In) composition (x-axis) in AlGaInN barrier layer 410. Here, InGaN active layer 420 is composed of In_{0.1}Ga_{0.9}N and has a thickness of 3 nm. AlGaInN barrier layer 410 is composed of Al_{0.1}Ga_{0.9-y}In_{y}N and has a thickness of about 3 nm to 15 nm. Variable y, which indicates the mole fraction of indium (In) composition of Al_{0.1}Ga_{0.9-y}In_{y}N barrier layer 410, may be controlled such that the sum P_{PZ}^{w}+P_{SP}^{w} of the piezoelectric and spontaneous polarizations in InGaN active layer 420 and the sum P_{PZ}^{b}+P_{SP}^{b} of the piezoelectric and spontaneous polarizations in AlGaInN barrier layer 410 are substantially the same. The cancellation of the sum of piezoelectric and spontaneous polarizations between InGaN active layer 420 and AlGaInN barrier layer 410 makes a total internal polarization field in InGaN active layer 420 zero as defined in Equation (6).

As depicted in FIG. 5, the solid line indicates the sum (P_{PZ}^{w}+P_{SP}^{w}) of the piezoelectric and spontaneous polarizations in the quantum well formed in InGaN active layer 420. The dotted or dashed line indicates the sum (P_{PZ}^{b}+P_{SP}^{b}) of the piezoelectric and spontaneous polarizations in AlGaInN barrier layer 410. An experimental test showed that the solid line meets the dotted line when the indium (In) composition (y) in Al_{0.1}Ga_{0.9-y}In_{y}N barrier layer 410 has a mole fraction of approximately 0.16. Because the sum P_{PZ}^{w}+P_{SP}^{w} and the sum P_{PZ}^{b}+P_{SP}^{b} are substantially the same at the point where the solid and dotted lines meet, the internal polarization field in InGaN active layer 420 becomes approximately zero according to Equation (6). Accordingly, when variable y is approximately 0.16, that is, AlGaInN barrier layer 410 has the composition of Al_{0.1}Ga_{0.74}In_{0.16}N, the internal polarization field becomes approximately zero. Through the minimization of the internal polarization field, relaxation time τᵢₙ is largely reduced and the optical gain g(ω) of semiconductor device 400 can be maximized in accordance with reduction of relaxation time, as illustrated above with respect to Equations (1) through (5).

Compositions of InGaN active layer 420 and AlGaInN barrier layer 410 can be controlled. The graph shown in FIG. 6 illustrates the relationship between In composition of InGaN active layer 420 (having a thickness of 3 nm) and In composition of AlGaInN barrier layer 410 (having a thickness of about 3 nm to 15 nm) when the internal polarization field is zero. In the graph of FIG. 6, x-axis indicates the mole fraction of In composition of InGaN active layer 420, y-axis indicates the mole fraction of In composition of AlGaInN barrier layer 410, and the linear line indicates the points where the internal polarization field in InGaN active layer 420 has a zero value.

As shown in the graph of FIG. 6, the internal polarization field can be approximately zero when In compositions (variable x and y) of InGaN active layer 420 and AlGaInN barrier layer 410 are approximately 0.05 and 0.11, respectively (black square (a) on the linear line). In this case, InGaN active layer 420 has the composition of In_{0.05}Ga_{0.95}N and AlGaInN barrier layer 410 has the composition of Al_{0.1}Ga_{0.79}In_{0.11}N. Further, at the black square (b) on the linear line (that is, x and y are 0.1 and 0.16, respectively), III-V group compound semiconductor device 400 has In_{0.1}Ga_{0.9}N active layer and Al_{0.1}Ga_{0.74}In_{0.16}N barrier layer, and the internal polarization field becomes approximately zero. Still further, at the black square (c) on the linear line (that is, x and y are approximately 0.15 and 0.21, respectively), III-V group compound semiconductor device 400 has In_{0.15}Ga_{0.85}N active layer and Al_{0.1}Ga_{0.69}In_{0.21}N barrier layer, and the internal polarization field becomes approximately zero.

In some embodiments, by using the linear line as shown in FIG. 6, In composition (y) of AlGaInN barrier layer 410 and/or In composition (x) of InGaN active layer 420 can be selected to achieve zero internal polarization field in InGaN active layer 420. In some embodiments, In composition (x) of InₓGa₁₋ₓN active layer 420 can be in the range of about zero (0) and 0.3, and In composition (y) of Al_{0.1}Ga_{0.9-y}In_{y}N barrier layer 410 can be in the range of about 0.01 and 0.3. In other embodiments, In composition (x) of InₓGa₁₋ₓN active layer 420 is in the range of about 0.05 and 0.15, and In composition (y) of Al_{0.1}Ga_{0.9-y}In_{y}N barrier layer 410 can be in the range of about 0.1 and 0.22.

In some embodiments, the mole fractions of Al, Ga, and In compositions of AlGaInN barrier layer 410 can be controlled to accomplish zero internal polarization field. For example, AlGaInN barrier layer 410 can have a composition of Al_{y1}Ga_{1-y1-y2}In_{y2}N (0≦y+y2≦1). Variables y1 and y2 denote the mole fractions of Al and In compositions, respectively. A subtraction of y1 and y2 from one, that is, 1-y1-y2 denotes the mole fraction of Ga composition of AlGaInN barrier layer 410. For example, y1 can be in the range of about 0.05 to 0.3, and y2 can be in the range of about 0.1 and 0.22, in order to reduce the internal polarization field or accomplish the zero internal polarization field.

In some embodiments, the relationship between III-V group compound semiconductor materials of an active layer and a barrier layer can show non-linear relationship, such as logarithmic or exponential relationship in accordance with the type of the III-V group compound semiconductor materials of the active layer and the barrier layer and the variety of compositions of the III-V group compound semiconductor materials.

In some embodiments, the mole fractions of In compositions of InGaN active layer 420 and AlGaInN barrier layer 410 can be selected in consideration of the compressive strain of InGaN active and AnGaInN barrier layers 420 and 410. Since the higher In composition (e.g., about 0.3 or more) results in larger compressive strain and the growth of the strained layers is limited to a critical thickness, the lower In composition (e.g., about 0.01 to 0.1) can be selected.

As illustrated above, a scattering rate in a quantum well decreases as an internal polarization field in the quantum well decreases. Accordingly, by reducing the internal polarization field, the scattering rate can be decreased, and thus the relaxation time can be decreased. This results in the enhancement of the optical gain. The change of the scattering rate for different values of internal polarization field is illustrated in FIG. 7.

As depicted in FIG. 7, a graph plots a scattering rate (y-axis) of electrons and holes in active layer 420 as a function of Eₜ/ω_{q} (x-axis) for different values of an internal polarization field F in active layer 420. In the graph, solid lines indicate when internal polarization field F is 200 kV/F and dotted lines indicate when internal polarization field F is 0 kV/F. Eₜ is a transition energy level, is the Plank constant, and ω_{q} is a phonon angular frequency. As shown in the graph, when the intensity of internal polarization field F is very small (i.e. when F=0), the scattering rate is low for both holes and electrons. As illustrated above, the low scattering rate results in a short relaxation time, and thus a high optical gain.

The graph shown in FIG. 8 illustrates an optical gain (y-axis) of III-V group compound semiconductor device 400 depicted in FIG. 4 and an InGaN/GaN semiconductor device as a function (x-axis) of a transition wavelength. As depicted in the graph of FIG. 8, III-V group compound semiconductor device 400 includes InₓGa₁₋ₓN active layer 420 and AlGaInN barrier layer 410, and the InGaN/GaN semiconductor device includes an InₓGa₁₋ₓN active layer and a GaN barrier layer. Assuming that variable x is 0.05, the peak optical gain of In_{0.5}Ga_{0.5}N/AlGaInN semiconductor device 400 is approximately 13,000/cm and the peak optical gain of the In_{0.5}Ga_{0.5}N/GaN semiconductor device is approximately 9,000/cm. The peak transition wavelength is shifted to a shorter region with a quaternary barrier layer, that is, AlGaInN barrier layer 410. InGaN/AlGaInN semiconductor device 400 has much larger optical gain than that of the InGaN/GaN semiconductor device because the relaxation time in InGaN/AlGaInN semiconductor device 400 is largely reduced due to disappearance of the internal polarization field.

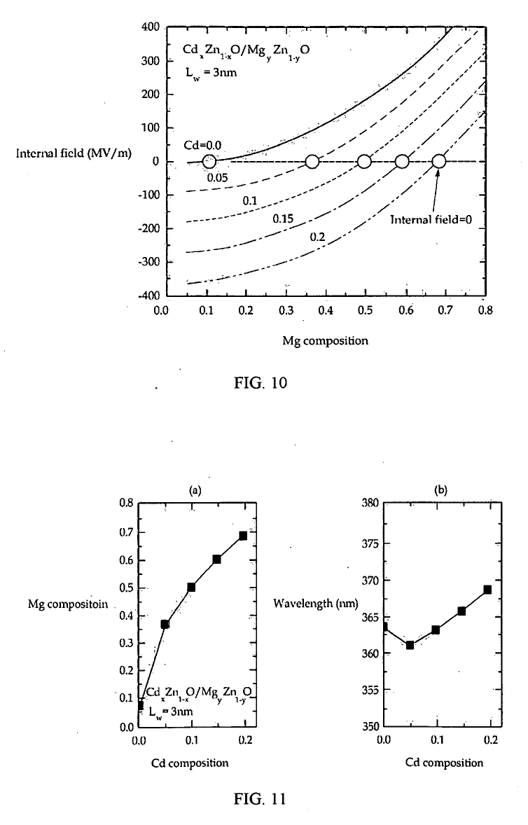

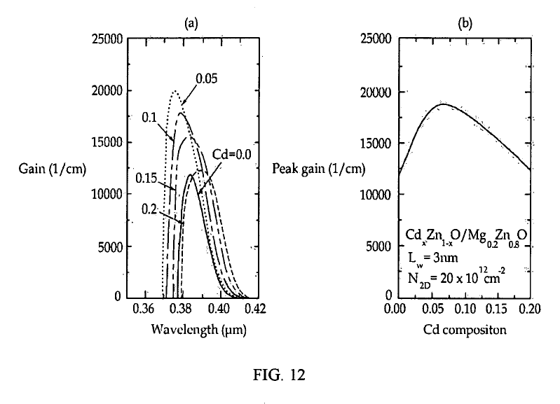

In other embodiments, a semiconductor device may have II-VI group compound. Such a II-VI group compound semiconductor device will now be described with reference to FIGS. 9-12. FIG. 9 is a schematic diagram of an illustrative embodiment of a II-VI group compound semiconductor device. FIG. 10 is a graph showing internal polarization field as a function of Mg composition of the MgZnO barrier layer for different Cd compositions of the CdZnO active layer depicted in FIG. 9. FIG. 11 shows graphs illustrating (a) the relationship between Mg composition of the MgZnO barrier layer and Cd composition of the CdZnO active layer depicted in FIG. 9, and (b) a transition wavelength of the II-VI group compound semiconductor device as a function of Cd composition of the CdZnO active layer depicted in FIG. 9. FIG. 12 shows graphs illustrating (a) an optical gain as a function of a transition wavelength for different mole fractions of Cd compositions of the CdZnO active layer depicted in FIG. 9 and (b) an optical gain as a function of different mole fractions of Cd compositions of the CdZnO active layer depicted in FIG. 9.

With reference to FIG. 9, a II-VI group compound semiconductor device 900 includes a CdZnO active layer 920 (i.e., an active layer composed of CdZnO) and upper and lower MgZnO barrier layers 910 and 930 (i.e., upper and lower barrier layers each composed of MgZnO). Upper and lower MgZnO barrier layers 910 and 930 may be disposed on opposite surfaces (e.g. top and bottom surfaces) of CdZnO active layer 920 as depicted in FIG. 9. Alternatively, II-VI group compound semiconductor device 900 may have one barrier layer (e.g., upper MgZnO barrier layer 910) disposed on one surface (e.g., a top surface) of CdZnO active layer 920. In some embodiments, CdZnO Active layer 920 may have a thickness of several nanometers to several hundreds nanometers. In other embodiments, a thickness of active layer 920 may be about 0.1 nm to 300 nm, or about 1 nm to 50 nm.

In some embodiments, upper and lower MgZnO barrier layers 910 and 930 may each have a thickness of several nanometers to several hundreds nanometers. In other embodiments, upper and lower MgZnO barrier layers 910 and 930 may each have a thickness of about 0.1 nm to 500 nm or about 1 nm and to 100 nm. The II-VI group compound semiconductor material of the upper and lower barrier layers (e.g. upper and lower MgZnO barrier layers 910 and 930) have wider band gaps than that of the II-VI group compound semiconductor material of the active layer (e.g. CdZnO active layer 920), thus forming a quantum well in the active layer (e.g. CdZnO active layer 920). In other embodiments, a II-VI group compound semiconductor material having a wider band gap than that of a II-VI group semiconductor material of the active layer can be selected for the upper and lower barrier layers.

In some embodiments, CdZnO active layer 920 has a band gap of about 2.2 eV to 3.35 eV, and upper and lower MgZnO barrier layers 910 and 930 each have a band gap of about 3.35 eV to 5.3 eV. The band gaps of upper and lower MgZnO barrier layers 910 and 930 and CdZnO active layer 920 can vary depending on the compositions of Mg, Zn or Cd in upper and lower MgZnO barrier layers 910 and 920, and CdZnO active layer 930. Due to the differences between the band gaps of CdZnO active layer 920 and upper and lower MgZnO barrier layers 910 and 930, a quantum well is formed in CdZnO active layer 920. As illustrated with respect to Equation (6) above, the internal polarization field in the quantum well can be reduced by controlling the mole fractions of the compositions of CdZnO active layer 920 and/or upper and lower MgZnO barrier layers 910 and 930.

With reference to the graph shown in FIG. 10, an internal polarization field (y-axis) in CdZnO active layer 920 for different Cd compositions and Mg compositions (x-axis) in upper and lower MgZnO layers 910 and 920, and CdZnO active layer 930 will now be described in detail. Here, assume that CdZnO active layer 920 has a composition of CdₓZn₁₋ₓO (0≦x≦1) and a thickness of about 3 nm, and each of upper and lower MgZnO barrier layers 910 and 930 has a composition of Mg_{y}Zn_{1-y}O (0≦y≦1) and has a thickness of about 3 nm to 15 nm. As described for III-V group compound semiconductors 400 (depicted in FIG. 4) with respect to FIG. 5 above, the compositions of CdₓZn₁₋ₓO active layer 920 and upper and lower Mg_{y}Zn_{1-y}O barrier layers 910 and 930 may be controlled to make the internal polarization field in CdₓZn₁₋ₓO active layer 920 approximately zero.

As an example, when Cd composition of CdₓZn₁₋ₓO active layer 920 and Mg composition of Mg_{y}Zn_{1-y}O barrier layers 910 and 930 are approximately zero and 0.1, respectively, that is, II-VI group compound semiconductor device 900 has ZnO active layer 920 and upper and lower Mg_{0.1}Zn_{0.9}O barrier layers 910 and 930, the internal polarization field becomes approximately zero. As another example, the internal field becomes zero when variables x and y are approximately 0.05 and 0.37, 0.1 and 0.5, 0.15 and 0.6, or 0.2 and 0.7, respectively. In the case where variables x and y are 0.2 and 0.7, respectively, II-VI group compound semiconductor device 900 has Cd_{0.2}Zn_{0.80} active layer 920 and upper and lower Mg_{0.7}Zn_{0.30} barrier layers 910 and 930. When Cd composition (x) in CdₓZn₁₋ₓO active layer 920 is in the range of about zero (0) and 0.2, Mg composition (y) in upper and lower Mg_{y}Zn_{1-y}O barrier layers 910 and 930 can be in the range of about 0.01 and 0.8.

The relationship between Cd composition of CdZnO active layer 920 and Mg composition of each of upper and lower MgZnO barrier layers 910 and 930 is shown in graph (a) of FIG. 11. In graph (a), the solid line indicates when the internal polarization is zero. As shown in graph (a), Mg composition of upper and lower Mg_{y}Zn_{1-y}O barrier layers 910 and 930 increases in accordance with the increase of Cd composition of CdₓZn₁₋ₓO active layer 920 in the condition of zero internal polarization field. In this case, Mg composition of upper and lower Mg_{y}Zn_{1-y}O barrier layers 910 and 930 and Cd composition of CdₓZn₁₋ₓO active layer 920 are in a logarithmic relationship. In some embodiments, the relationship between II-VI group compound semiconductor materials of a barrier layer and an active layer at a zero internal polarization field can be inverse proportional or exponential depending on the type of the II-VI group compound semiconductor materials of the layers or various compositions of the II-VI group compound semiconductor materials. In some embodiments, a relationship between the II-VI group compound semiconductor materials of the barrier layer and the active layer at the zero internal polarization field can be linear depending on a type of the II-VI group compound semiconductor materials and compositions of the II-VI group compound semiconductor materials.

Graph (b) in FIG. 11 illustrates a transition wavelength of II-VI group compound semiconductor device 900 as a function of Cd composition of CdZnO active layer 920. As shown in graph (b), the transition wavelength of II-VI group semiconductor device 900 is changed by controlling Cd composition of CdZnO active layer 920. Therefore, Cd composition can be selected in accordance with a desirable transition wavelength for various optoelectronic devices. Further, Mg composition can be selected depending on the selected Cd composition to have substantially a zero internal polarization field in CdZnO active layer 920.

Graph (a) in FIG. 12 illustrates an optical gain (y-axis) as a function of the transition wavelength (x-axis) for different mole fractions of Cd compositions of CdZnO active layer 920 depicted in FIG. 9. Here, II-VI group compound semiconductor device 900 has CdₓZn₁₋ₓO active layer 920 and Mg_{0.2}Zn_{0.80} barrier layers 910 and 930. As illustrated in graph (a), the optical gain is correlated to the Cd composition. That is, the optical gain and the transition wavelength can be changed by controlling Cd composition of CdₓZn₁₋ₓO active layer 920. As can be seen in graph (a), when the mole fraction of Cd composition changes from zero to 0.05, the transition wavelength of II-VI group compound semiconductor device 900 is shifted to the left, that is, a peak wavelength of II-VI group compound semiconductor device 900 is reduced, and the optical gain of II-VI group compound semiconductor device 900 is increased. As an example, when the mole fraction of Cd composition is approximately zero, the peak wavelength is approximately 0.385 μm and the optical gain at the peak wavelength is approximately 12,500/cm. As another example, when the mole fraction of Cd composition is 0.05, the peak of the transition wavelength of II-VI group compound semiconductor device 900 is approximately 0.375 and the optical gain of II-VI group compound semiconductor device 900 is approximately 20,000/cm. Accordingly, the optical gain of II-VI group compound semiconductor device 900 can be enhanced by controlling the mole fraction of Cd composition of CdₓZn₁₋ₓO active layer 920.

Graph (b) in FIG. 12 illustrates the peak gain (y-axis) of II-VI group compound semiconductor device 900 as a function of Cd composition (x-axis) in CdZnO active layer 920. Here, II-VI group compound semiconductor device 900 has CdₓZn₁₋ₓO active layer 920 and upper and lower Mg_{0.2}Zn_{0.80} barrier layers 910 and 930. A thickness of CdₓZn₁₋ₓO active layer 920 is about 3 nm, and the carrier density (N_{2D}) in CdₓZn₁₋ₓO active layer 920, i.e. the number of carriers in CdₓZn₁₋ₓO active layer 920 per a square meter, is about 20*10¹² cm⁻². As shown in graph (b), the peak gain of II-VI group compound semiconductor device 900 can be changed for different Cd compositions of CdₓZn₁₋ₓO active layer 920. For example, II-VI group compound semiconductor device 900 can have the optical gain of approximately more than 17,000/cm when the mole fraction of Cd composition of CdₓZn₁₋ₓO active layer 920 is approximately 0.07.

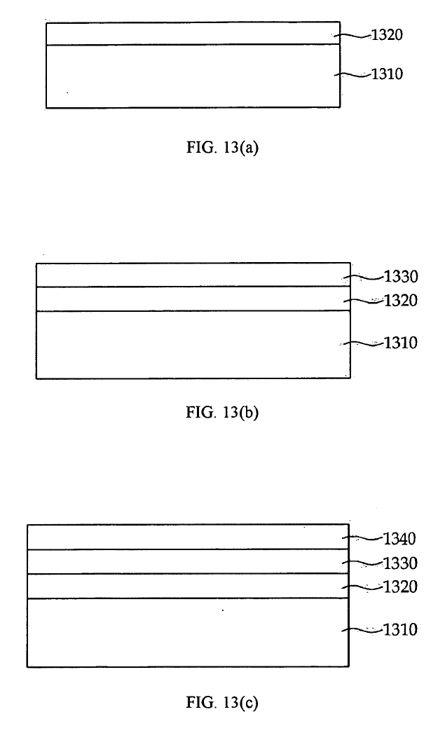

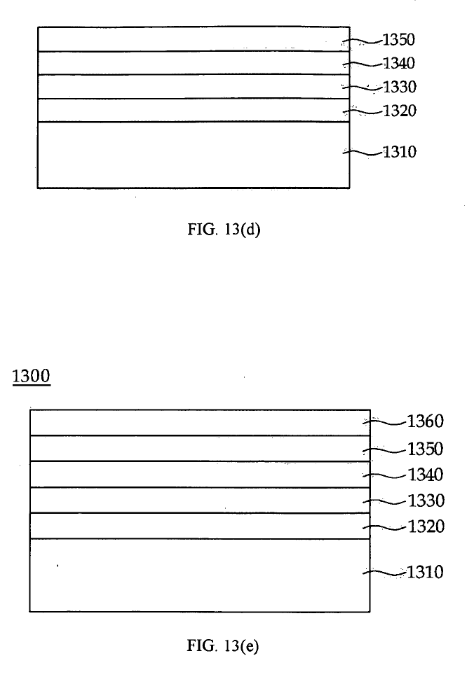

In some embodiments, a method for fabricating a semiconductor device is provided. FIGS. 13(a)-(e) are schematic diagrams of an illustrative embodiment of a method for fabricating a semiconductor device 1300.

As depicted in FIG. 13(a), a substrate 1310 is provided. Substrate 1310 may be composed of a C-face (0001) or A-face (1120) oriented sapphire (Al₂O₃). Alternatively, substrate 1310 may include silicon (Si), silicon carbide (SiC), spinel (MgAl2O4), aluminum nitride (AlN), gallium nitride (GaN), or aluminum gallium nitride (AlGaN) without limitation. A buffer layer 1320 can be optionally disposed on one surface (e.g. a top surface) of substrate 1310. Buffer layer 1320 can be made of a III-V group compound semiconductor material or a II-VI group compound semiconductor material. The material for buffer layer 1320 is not limited to the aforementioned III-V and II-VI groups, but may also include any material that establishes good structural quality. Buffer layer 1320 can have a thickness of from about 0.1 μm to 300 μm.

A lower barrier layer 1330 may be disposed on a top surface of buffer layer 1320, as depicted in FIG. 13(b). Lower barrier layer 1330 can include a III-V group compound semiconductor material or a II-VI group compound semiconductor material. Suitable materials and thickness for lower barrier layer 1330 are substantially the same as the materials and thickness described above for lower barrier layer 130. Lower barrier layer 1330 can be formed by using any deposition techniques known in the art, such as radio-frequency (RF) magnetron sputtering, pulsed laser deposition, metal organic chemical vapor deposition (MOCVD), molecular beam epitaxy, and radio-frequency plasma-excited molecular beam epitaxy, without limitation. The composition of lower barrier layer 1330 can be adjusted by controlling an amount of precursor gases provided to a deposition device (e.g. MOCVD) or by controlling a processing temperature or processing time.

As depicted in FIG. 13(c), an active layer 1340 is disposed over lower barrier layer 1330. Active layer 1340 can include a III-V group compound semiconductor material or a II-VI group compound semiconductor material. Suitable materials and thickness for active layer 1340 are substantially the same as the materials and thickness described above for active layer 120. Active layer 1340 can be formed by using any of the aforementioned deposition techniques known in the art.

In some embodiments, an upper barrier layer 1350 can be disposed on a top surface of active layer 1330, as depicted in FIG. 13(d). Upper barrier layer 1350 can be composed of the same material as lower barrier layer 1330. For example, upper barrier layer 1350 can include a III-V group compound semiconductor material or a II-VI group compound semiconductor material. Suitable materials and thickness for upper barrier layer 1350 are substantially the same as the materials and thicknesses described above for upper barrier layer 110. Upper barrier layer 1350 can be formed by using any of the aforementioned deposition techniques known in the art.

In some embodiments, lower barrier layer 1330 or upper barrier layer 1350 can be selectively disposed on active layer 1330. For example, semiconductor device 1300 can have lower barrier layer 1330 disposed on a bottom surface of active layer 1340, upper barrier layer 1350 disposed on a top surface of active layer 1340, or both lower and upper barrier layers 1330 and 1350 disposed on bottom and top surfaces of active layer 1340, respectively.

As described above, the III-V group compound semiconductor materials or the II-VI group compound semiconductor materials for active layer 1340 and/or upper and lower barrier layers 1350 and 1330 can be selected such that active layer 1340 has a narrower band gap than that of upper and lower barrier layers 1350 and 1330. This band gap difference forms a quantum well in active layer 1340.

As depicted in FIG. 13(e), an Electrode 1360 can be optionally disposed on a top surface of upper barrier layer 1350. Electrode 1360 can include conductive material such as an n-type doped semiconductor material, a p-type doped semiconductor material, or a metal. For example, Electrode 1360 can include, without limitation, Al, Ti, Ni, Au, Ti/Al, Ni/Au, Ti/Al/Ti/Au, or an alloy thereof. Electrode 1360 can be formed to have a thickness of about 1 nm to 300 nm, or about 5 nm to 50 nm. Electrode 1360 may be formed by using any techniques known in the art, such as sputtering, electroplating, e-beam evaporation, thermal evaporation, laser-induced evaporation, and ion-beam induced evaporation, without limitation.

Accordingly, a II-VI or III-V group compound semiconductor device in accordance with one embodiment can an reduce internal polarization field in a quantum well by forming an upper and/or lower barrier layer of II-VI group compound on at least one active layer of II-VI group compound, or forming an upper and/or lower barrier layer of III-V group compound on at least one active layer of III-V group compound. Further, the II-VI or III-V group compound semiconductor device can reduce the internal polarization field in the quantum well by controlling the mole fractions of a II-VI group compound or III-V group compound in the active layer, the upper barrier layer, and/or the lower barrier layer. Through the reduction of the internal polarization field in the quantum well, a relaxation time of the electrons or holes in the active layer is reduced and the optical gain of the semiconductor device is enhanced.

In some embodiments, a photo-electric conversion device, an optoelectronic device, or a quantized electronic device in which the semiconductor device described above is installed can be provided. For example, a short wavelength emitter, a photo detector, a laser, a high electron mobility transistor, or a light emitting device can include a semiconductor device. The semiconductor device includes at least one active layer and at least one barrier layer formed on at least one surface of the active layer. Each of the active layer and the barrier layer is composed of a III-V or II-VI group compound semiconductor material. The barrier layer has a wider band gap than that of the active layer.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A semiconductor device comprising:
at least one active layer composed of a first compound; and
at least one barrier layer composed of a second compound and disposed on at least one surface of the at least one active layer,
wherein an energy band gap of the at least one barrier layer is wider than an energy band gap of the at least one active layer and
the first and/or second compounds are selected to reduce a relaxation time of an electron or hole in the at least one active layer.

2. The semiconductor device of claim 1, wherein compositions of the first and/or second compounds are selected to reduce a scattering rate of the electron or hole in the at least one active layer to reduce the relaxation time.

3. The semiconductor device of claim 2, wherein the compositions of the first and/or second compounds are further selected to reduce an internal polarization field in the at least one active layer to reduce the scattering rate.

4. The semiconductor device of claim 3, wherein the compositions of the first and/or second compounds are selected to make a sum of piezoelectric and spontaneous polarizations in the at least one active layer and a sum of piezoelectric and spontaneous polarizations in the at least one barrier layer substantially the same to reduce the internal polarization field.

5. The semiconductor device of claim 1, wherein each of the first and second compounds comprises a III-V group compound semiconductor material or a II-VI group compound semiconductor material.

6. The semiconductor device of claim 1, wherein the first compound comprises GaN, InGaN, CdZnO, AlN, AlP, AlAs, GaP, GaAs, InN, InP, InAs, AlGaN, AlGaP, AlGaAs, InGaN, InGaP, InGaAs, INAlN, InAlP, InAlAs, AlGaInN, AlGaInP, AlGaInAs, ZnO, ZnS, CdO, CdS, CdZnS, CdZnO, MgZnO, MgZnS, CdMgZnO, or CdMgZnS.

7. The semiconductor device of claim 1, wherein the second compound comprises AlInGaN, InGaN, AlGaN, AlGaP, AlGaAs, InGaN, InGaP, InGaAs, INAlN, InAlP, InAlAs, AlGaInP, AlGaInAs, CdZnS, CdZnO, MgZnO, MgZnS, CdMgZnO, or CdMgZnS.

8. The semiconductor device of claim 1, wherein the first compound comprises InₓGa₁₋ₓN (0≦x≦1) and the second compound comprises Al_{y1}Ga_{1-y1-y2}In_{y2}N (0≦y1+y2≦1).

9. The semiconductor device of claim 8, wherein x is in the range of about 0.05 and 0.15, y1 is in the range of about 0.05 to 0.3, and y2 is in the range of about 0.1 and 0.22.

10. The semiconductor device of claim 1, wherein the first compound comprises CdₓZn₁₋ₓO (0≦x≦1) and the second compound comprises Mg_{y}Zn_{1-y}O (0≦y≦1).

11. The semiconductor device of claim 10, wherein x is in the range of about 0 and 0.20 and y is in the range of about 0.01 and 0.80.

12. The semiconductor device of claim 1, wherein the at least one active layer has a thickness of about 0.1 nm to 300 nm, and the at least one barrier layer has a thickness of about 0.1 nm to 500 nm.

13. The semiconductor device of claim 1, wherein the energy band gap of the at least one active layer is in the range of about 0.7 eV and 3.4 eV, and the energy band gap of the at least one barrier layer is in the range of about 0.7 eV and 6.3 eV.

14. The semiconductor device of claim 1, wherein the energy band gap of the at least one active layer is in the range of about 2.2 eV and 3.35 eV and the energy band gap of the at least one barrier layer is in the range of about 3.35 eV and 5.3 eV.

15. A method for fabricating a semiconductor device comprising:
forming at least one active layer composed of a first compound on a substrate; and
forming at least one barrier layer on at least one surface of the at least one active layer, the at least one barrier layer composed of a second compound,
wherein an energy band gap of the at least one barrier layer is wider than an energy band gap of the at least one active layer, and
wherein compositions of the first and/or second compounds are adjusted to reduce a relaxation time of an electron or hole in the at least one active layer.

16. The method of claim 15, wherein the compositions of the first and/or second compounds are further adjusted to reduce an internal polarization field in the at least one active layer.

17. The method of claim 16, wherein each of the first and second compounds comprises a III-V group compound semiconductor material or a II-VI group compound semiconductor material.

18. The method of claim 15, wherein when the first compound comprises InₓGa₁₋ₓN and the second compound comprises Al_{y1}Ga_{1-y1-y2}In_{y2}N, the adjusting of the compositions of the first and/or second compounds comprises controlling a variable x in the range of 0-1, and a sum of variables y1 and y2 in the range of 0-1.

19. The method of claim 15, wherein when the first compound comprises CdₓZn₁₋ₓO and the second compound comprises Mg_{y}Zn_{1-y}O, the adjusting of the compositions of the first and/or second compounds comprises controlling each of variables x and y in the range of about 0-1.

20. The method of claim 15, wherein the at least one active layer has a thickness of about 0.1 nm to 300 nm and the at least one barrier layer has a thickness of about 0.1 nm to 500 nm.

21. The method of claim 15, wherein either forming the at least one active layer or forming the at least one barrier layer comprises employing radio-frequency (RF) magnetron sputtering, pulsed laser deposition, metal organic chemical vapor deposition (MOCVD), molecular beam epitaxy, or radio-frequency plasma-excited molecular beam epitaxy.

22. The method of claim 21, wherein the compositions of the first and/or second compounds are adjusted by controlling an amount of precursor gases or by controlling a processing temperature or processing time to reduce the relaxation time of the electron or hole in the at least one active layer.
